(19) United States
(12) Patent Application Publication
(10) Pub. No.: US 2026/0098927 A1
(43) Pub. Date: Apr. 9, 2026

(54) TEST AND/OR MEASUREMENT SYSTEM AND METHOD FOR CALIBRATING A TEST AND/OR MEASUREMENT SYSTEM

(71) Applicant: Rohde & Schwarz GmbH & Co. KG, Munich (DE)

(72) Inventors: Thilo BEDNORZ, Erding (DE); Walter WEISS, Poing (DE)

(21) Appl. No.: 18/910,864

(22) Filed: Oct. 9, 2024

(51) Int. Cl. G01R 35/00; G01R 27/28; G01R 31/28

(52) U.S. Cl. CPC G01R 35/005; G01R 27/28; G01R 31/2822

(57) ABSTRACT

The present disclosure relates to a test and/or measurement system. The test and/or measurement system comprises: a vector network analyzer, VNA, comprising a test port for forwarding RF signals; a switch matrix comprising an input port which is arranged for being connected to the test port of the VNA, and a plurality of output ports which are arranged for being connected to a device-under-test, wherein the switch matrix is configured to electrically connect the input port to one of the plurality of output ports. The test and/or measurement system further comprises an inline calibration unit which is switched between the test port of the VNA and the input port of the switch matrix; wherein the inline calibration unit comprises at least three different calibration standards; wherein the inline calibration unit is operable in a calibration mode and in a normal mode; wherein, in the calibration mode, the inline calibration unit is configured to alternately connect the at least three different calibration standards to the test port of the VNA; and, wherein, in the normal mode, the inline calibration unit is configured forward an RF signal received from the VNA to the switch matrix.

### TECHNICAL FIELD

The disclosure relates to a test and/or measurement system, which comprises a vector network analyzer and a switch matrix, and to a method for calibrating such a test and/or measurement system.

### BACKGROUND ART

A vector network analyzer (VNA) is a device for measuring the RF performance of a radio frequency device-under-test (DUT) or of an electrical network. The VNA can be used to characterize scattering parameters (S-parameters) of the DUT. For multiport applications, switch matrixes can be connected to the VNA in order to increase the number of VNA ports.

A Measurement with a VNA requires a high accuracy and repeatability. A drift in the VNA (e.g., caused by temperature variations) can negatively affect the accuracy of the measurement result. The use of a switch matrix can amplify the effect of VNA drifts on the measurement result, because the error-to-signal ratio is amplified by attenuation of the switch paths in the switch matrix.

To mitigate this issue, a time-consuming recalibration might be necessary much earlier than without using the switch matrix. For instance, to perform such recalibrations, each port of the switch matrix is connected to a calibration module. However, when using a switch matrix with a large number of ports, this becomes expensive and requires a lot of space in the immediate vicinity of the DUT.

### SUMMARY

Thus, there is a need to provide an improved test and/or measurement system and an improved method for calibrating a test and/or measurement system, which avoid the above-mentioned disadvantages.

These and other objectives are achieved by the embodiments provided in the enclosed independent claims. Advantageous implementations of the present disclosure are further defined in the dependent claims.

According to a first aspect, the disclosure relates to a test and/or measurement system. The test and/or measurement system comprises: a vector network analyzer (VNA) comprising a test port for forwarding radio frequency (RF) signals; a switch matrix comprising an input port which is arranged for being connected to the test port of the VNA, and a plurality of output ports which are arranged for being connected to a device-under-test, wherein the switch matrix is configured to electrically connect the input port to one of the plurality of output ports. The test and/or measurement system further comprises an inline calibration unit which is switched between the test port of the VNA and the input port of the switch matrix; wherein the inline calibration unit comprises at least three different calibration standards. The inline calibration unit is operable in a calibration mode and in a normal mode; wherein, in the calibration mode, the inline calibration unit is configured to alternately connect the at least three different calibration standards to the test port of the VNA; and, in the normal mode, the inline calibration unit is configured forward an RF signal received from the VNA to the switch matrix.

This achieves the advantage that a calibration of a VNA with a connected switch matrix can be carried out in a calibration plane before the switch matrix. This reduces the number of required calibration modules and simplifies the setup compared to a calibration on the switch matrix output ports, because the number of VNA test ports (and switch matrix input ports) is usually much lower than the number of switch matrix output ports. Furthermore, the VNA accounts for most of the total drift of the system. Therefore, carrying out the calibration measurements between the VNA and the switch matrix is sufficient to correct most of the drift.

In an embodiment, the VNA is configured to perform a first calibration measurement if the first inline calibration unit is operated in the calibration mode; wherein the first calibration measurement comprises calculating a first set of error terms.

In an embodiment, the VNA is configured to perform a second calibration measurement if the inline calibration unit is operated in the normal mode; wherein during the second calibration measurement at least three different calibration standards are alternately connected to a number of output ports of the switch matrix which are alternately connected to the input port; and wherein the second calibration measurement comprises calculating a second set of error terms.

To perform the second calibration measurement, one or more calibration modules (or units) can be connected to the output ports of the switch matrix. These calibration modules (or units) can comprise the at least three calibration standards (e.g., open, short and match).

In an embodiment, the VNA is configured to perform the first calibration measurement more frequently than the second calibration measurement.

Typically, the VNA exhibits a much stronger drift than the switch matrix. Therefore, it can be sufficient to perform the first calibration measurement (which detects VNA drift) more often than the second calibration measurement. For instance, the second calibration measurement is only carried out if the first set of error terms was previously calculated.

In an embodiment, the inline calibration unit is arranged in a housing of the VNA, a housing of the switch matrix, or a separate housing.

In an embodiment, the inline calibration unit comprises an impedance tuner and/or a power meter and/or a phase reference.

In an embodiment, the VNA comprises a further test port for forwarding RF signals; wherein the switch matrix comprises a further input port which is arranged for being connected to the further test port of the VNA, wherein the switch matrix is configured to electrically connect the further input port to a further one of the plurality of output ports.

In an embodiment, the test and/or measurement system comprises a further inline calibration unit which is switched between the further output port of the VNA and the further input port of the switch matrix; wherein the further inline calibration unit comprises at least three different further calibration standards. For example, the three calibration standards comprise open, short and match.

In an embodiment, the further inline calibration unit is operable in a calibration mode and in a normal mode; wherein, in the calibration mode, the further inline calibration unit is configured to alternately connect the at least three different further calibration standards to the further test port of the VNA; and, in the normal mode, the further inline calibration unit is configured forward an RF signal received from the VNA to the switch matrix. The further calibration standards of the further inline calibration unit can be identical to the calibration standards of the inline calibration unit.

In an embodiment, the inline calibration unit and the further inline calibration unit are configured to at least temporarily establish a through connection between the test port and the further test port of the VNA when they operate in the calibration mode.

In an embodiment, the inline calibration unit and the further inline calibration unit are arranged in a shared housing or in separate housings or in the switch matrix or in the VNA.

In an embodiment, the VNA is configured to control the calibration unit and the further calibration unit to be in the calibration mode or the normal mode.

In an embodiment, the VNA comprises a number of test ports, wherein the system comprises one inline calibration unit for each of the number of test ports. For instance, the VNA can have 2 to 4 test ports. However, also a large number of test ports is possible.

According to a second aspect, the disclosure relates to a method for calibrating a test and/or measurement system, wherein the test and/or measurement system comprises a vector network analyzer, VNA, and a switch matrix; wherein the VNA comprise a test port for forwarding RF signals, and wherein the switch matrix comprises an input port and a plurality of output ports. The method comprises the steps of: switching an inline calibration unit between the test port of the VNA and the input port of the switch matrix, wherein the inline calibration unit comprises at least three different calibration standards; performing a first calibration measurement comprising the steps of: alternately connecting the at least three different calibration standards to the test port of the VNA, and calculating a first set of error terms with the VNA; and performing a second calibration measurement comprising the steps of: alternately connecting at least three different calibration standards to a number of output ports of the switch matrix alternately connecting the number of output ports of the switch matrix to the VNA, and calculating a second set of error terms with the VNA.

In an embodiment, the method comprises the further step of adjusting the VNA based on the calculated first and/or second set of error terms. For example, internal settings of the VNA can be adjusted based on the first and/or the second set of error terms to correct a drift.

### BRIEF DESCRIPTION OF THE DRAWINGS

The above-described aspects and implementation forms of the present disclosure will be explained in the following description of specific embodiments in relation to the enclosed drawings, in which:

FIG. 1 shows a schematic diagram of a test and/or measurement system according to an embodiment;

FIG. 2 shows a schematic diagram of a test and/or measurement system according to an embodiment;

FIG. 3 shows a schematic diagram of a test and/or measurement system according to an embodiment; and

FIG. 4 shows a flow chart of a method for calibrating a test and/or measurement system according to an embodiment.

### DETAILED DESCRIPTIONS OF EMBODIMENTS

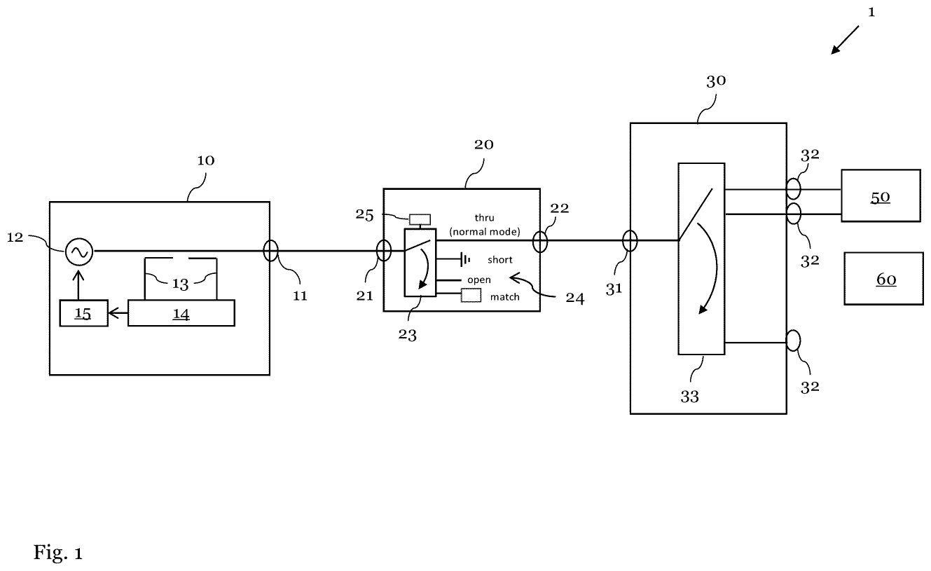

FIG. 1 shows a schematic diagram of a test and/or measurement system 1 according to an embodiment.

The test and/or measurement system 1 comprises a vector network analyzer (VNA) 10 which comprises a test port 11 for forwarding RF signals and a switch matrix 30. The switch matrix 30 comprises an input port 31 which is arranged for being connected to the test port 11 of the VNA 10 and a plurality of output ports 32 which are arranged for being connected to a device-under-test (DUT) 50, wherein the switch matrix 30 is configured to electrically connect the input port to one of the plurality of output ports 32.

The test and/or measurement system 1 further comprises an inline calibration unit 20 which is switched between the test port 11 of the VNA 10 and the input port 31 of the switch matrix 30; wherein the inline calibration unit 20 comprises at least three different calibration standards 24; and wherein the inline calibration unit 20 is operable in a calibration mode and in a normal mode. In the calibration mode, the inline calibration unit 20 is configured to alternately connect the at least three different calibration standards 24 to the test port of the VNA; and, in the normal mode, the inline calibration unit 20 is configured forward an RF signal received from the VNA to the switch matrix.

For example, the inline calibration unit comprises a first port 21 which is connected to the test port 11 of the VNA 10 and a second port 22 which is connected to the input port 31 of the switch matrix 30. The inline calibration unit 20 can comprise a through connection which connects its first port to its second port. In the normal mode, the inline calibration unit can use the through connection to forward RF signals from the VNA 10 to the switch matrix 30, or vice versa. For instance, in the normal mode, the inline calibration unit can forward RF signals from the VNA to switch matrix, or vice versa. In this way, an S-parameter measurement of a DUT 50 connected to the switch matrix 30 can be carried out with the VNA 10.

For example, the calibration standards 24 of the inline calibration unit 20 comprise an open, a short and a match calibration standard. In the calibration mode, the inline calibration unit 20 can alternately connect the test port 11 to the open, short and match (e.g., to perform an OSM calibration). The inline calibration unit 20 can comprise an internal switch 23 which is configured to selectively connect its first port 21 to the through connection (in normal mode) or to one of the calibration standards 24 (in calibration mode).

The calibration module can also comprise two “one-port standards” (e.g. two of open, short and match) and one “two-port standard” (e.g., trough). For instance, the inline calibration unit 20 comprises at least an open, a short and a match calibration standard if the VNA has one port; or the inline calibration unit 20 comprises at least an open, a short and a through calibration standard if the VNA has at least two ports. In the latter case, the calibration unit 20 could also comprise open, short and match (instead of through).

The switch matrix 30 can comprise at least one switch 33, for instance a mechanical or a solid state switch, which is configured to connect the input port 31 to one of a number of its output ports 32 or to one of all of its output ports 32. The designations “input” and “output” for the input and output ports 31, 32 of the switch matrix 30 do not limit these ports to only one transmission direction. Depending on the measurement currently performed, RF signals can be transmitted in both directions through these ports 31, 32.

The VNA 10 can comprise a signal generator 12 for generating RF signals. The signal generator 12 can be connected to the test port 11 via a signaling line. The VNA 10 can further comprise a first coupler unit 13 for coupling out a portion of an RF signal which is transmitted from the signal generator to the test port 11 over the signaling line, and a second coupler unit 13 for coupling out a portion of an RF signal which is received at the test port, wherein the coupled-out portions of the RF signals can be forwarded to a measurement unit 14 which is connected to a processor 15. In this way, the VNA 10 can analyze RF signals which are transmitted and received via the test port(s), e.g., for carrying out an S-parameter and/or a calibration measurement.

If the inline calibration unit 20 is in the calibration mode, the VNA 10 can be configured to perform a first calibration measurement. The first calibration measurement can comprise alternately connecting the test port 11 to the calibration standards 24 and calculating a first set of error terms.

In this way, a calibration can be carried out in a calibration plane after the VNA test ports 11 but before the switch matrix 30. This is advantageous, because the number of VNA test ports 11 is typically much lower than the number of switch matrix output ports 32 and, therefore, less calibration units 20 and/or less individual calibration measurements are required. The VNA 10 usually accounts for most of the total drift of the system 1. Thus, by calibrating on the VNA test ports 11, the largest drift effects can be detected and removed. For instance, the first set of error terms can comprise information on the system 1 (e.g., on a drift) up to the first port 21 of the inline calibration unit.

The VNA 10 can be recalibrated based on the results of the first calibration measurement only. By comparing these data (i.e., the first set of error terms) to previous data, a drift of the VNA 10 can be detected and its impact on a user calibration and/or the measurement results of the DUT 50 can be corrected. For instance, correction terms for the VNA can be calculated based on the results of the calibration measurement.

The VNA 10 can be configured to perform a second calibration measurement if the inline calibration unit is operated in the normal mode. For the second calibration measurement, at least three different calibration standards are alternately connected to a number of output ports 32 of the switch matrix 30. This can be carried out by connecting one or more calibration modules 60, which comprise the at least three different calibration standards, to number of output ports 32, which are alternately connected to the input port 31 when carrying out the second calibration measurement.

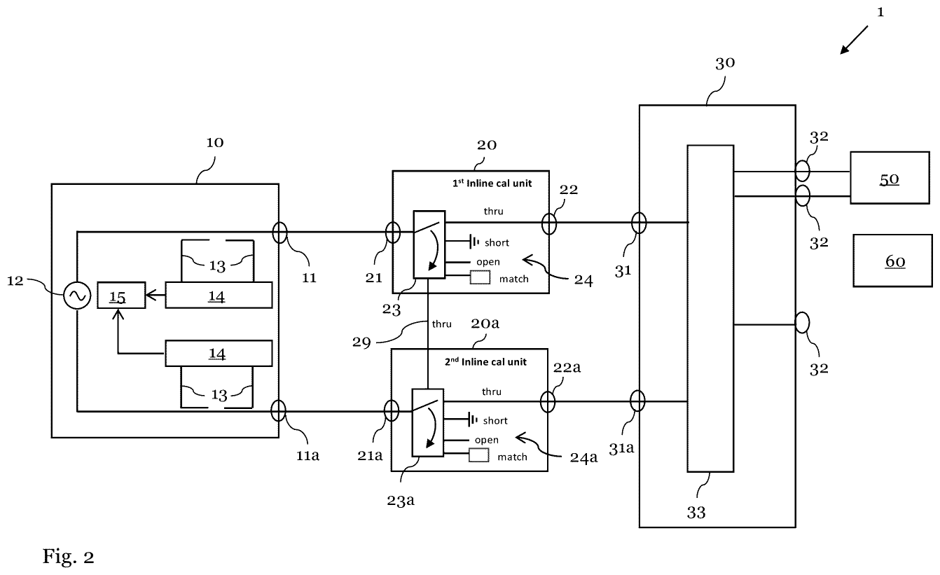

The at least three calibration standards which are connected to the output ports 32 during the second calibration measurement can comprise open, short and match (OSM). Alternatively, the at least three calibration standards can comprise two one-port calibration standards (e.g., OM) and a through connection between two output ports 32. In the latter case, two input ports 31 of the switch matrix 30 are required (as shown in FIG. 2).

The second calibration measurement can comprise calculating a second set of error terms. By means of the second calibration measurement, a drift of the system 1 at the output ports 32 of the switch matrix 30 can be detected.

The second calibration measurement can be a user calibration of the system. Due to the large number of output ports 32 of the switch matrix 30 (compared to the number of test ports 11), the second calibration measurement may require more effort, time and calibration devices than the first calibration measurement.

The VNA can be configured to calculate the first set of error terms more often than the second set of error terms. In other words: the first calibration measurement can be carried out more frequently than the second calibration measurement. This can be sufficient because the VNA drift, which is detected with the first calibration measurement, is expected to be much stronger than the additional drift caused by the switches of the switch matrix 30. At the time, the first calibration measurement can be carried out much faster and requires fewer devices than the second calibration measurement, due to the lower number of test ports 11 compared to the switch matrix output ports 32.

For example, the second set of error terms is only calculated (via the second calibration measurement) when the first set of error terms was previously calculated based on measurements with the inline calibration unit 20.

The VNA 10 can adjust its internal settings after each calibration measurement based on the calculated first and/or second set of error terms. By adjusting its internal settings, e.g. the settings of the signal generator 12, the VNA 10 can correct for the drift.

The inline calibration unit 20 can be arranged: a) in a housing of the VNA 10; or b) in a separate housing between the VNA 10 and the switch matrix 30; or c) in a housing of the switch matrix 30. In case the inline calibration unit 20 is arranged in the housing of the switch matrix 30, it can be arranged directly after the input port 31 or after a first switch 33 or switch row (e.g., in a lower level of the switch matrix 30).

The inline calibration unit 20 can comprise a measurement device 25, for instance an impedance tuner and/or a power meter and/or a phase reference for characterizing an RF signal.

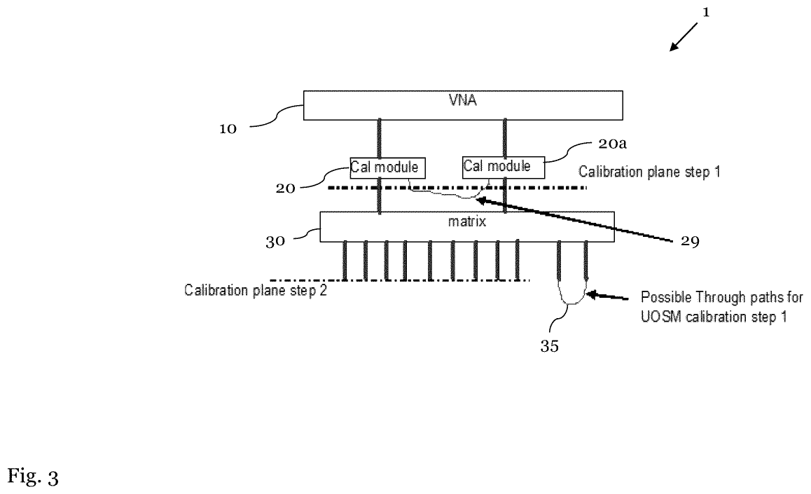

FIGS. 2 and 3 show exemplary embodiments of the test and/or measurement system 1, which build on the system 1 in FIG. 1. Same elements are labelled with the same reference signs. Hereinafter, only the differences between FIG. 1 and FIGS. 2 to 3 are explained.

As shown in FIG. 2, the test and/or measurement system 1 can comprise at least one further test port 11a for forwarding RF signals, and the switch matrix 30 can comprise a further input port 31a which is arranged for being connected to the further test port 11a of the VNA, wherein the switch matrix 30 is configured to electrically connect the further input port 31a to a further one of the plurality of output ports 32. For instance, the two input ports 31, 31a of the switch matrix 30 can be connected to different output ports 32.

The system 1 can comprise a further incline calibration unit 20a which is switched between the further test port 11a of the VNA 10 and the further input port 31a of the switch matrix 30. For instance, a first port 21a of the further calibration unit 20a is connected to the further test port 11a and a further second port 22a of the calibration unit 20a is connected to the further input port 31a of the switch matrix 30. The further inline calibration unit 20a can comprise at least three different calibration standards 24a. In the following, the inline calibration unit 20 and the further inline calibration unit 20a are referred to as the first and second inline calibration unit (according to the labelling in FIG. 2).

The first and the second inline calibration unit 20, 20a can have an identical structure and have the same basic functions.

For instance, the second inline calibration unit 20a is operable in a calibration mode and in a normal mode. In the calibration mode, the further inline calibration unit 20a can be configured to alternately connect it's at least three different calibration standards 24a to the further test port 11a of the VNA. In the normal mode, the further inline calibration unit 20a can be configured to forward an RF signal (e.g., a source signal) received from the VNA 10 to the switch matrix 30. In the normal mode, the further inline calibration unit 20a can also forward signals received from the switch matrix 30 to the VNA 10.

In the VNA 10, the signal generator 12 can be connected to the further test port 11a via a further signaling line. Further first and second coupler units 13 can be arranged to couple out portions of an RF signal which is forwarded to or received at the further test port 13, wherein the coupled out portions of the RF signals can be forwarded to a further measurement unit 14 which is connected to the processor 15. In this way, the VNA 10 can analyze RF signals which are transmitted and received via the further test port 11a. The VNA 10 can have additional test ports, e.g. a total number of four or more test ports. The basic structure and function of each VNA test port can be identical.

The first and the second inline calibration unit 20, 20a can be arranged within the same housing or in different housings.

The VNA 10 can control the first and the second calibration unit 20, 20a to change their respective modes. I.e., the VNA 10 can set the calibration units 20, 20a to the calibration mode or the normal mode. Therefore, the VNA 10 can be connected to the calibration units 20, 20a via communication connection (e.g., a USB connection).

The first and the second inline calibration unit 20, 20a can be connected to each other via a further through connection 29. For instance, the internal switches 23, 23a of the calibration units 20, 20a can connect the respective first ports 21, 21a to the further through connection 29. This through connection 29 can be established when the calibration units 20, 20a operate in calibration mode in order to perform a two-port calibration of the VNA 10.

The VNA 10 can comprise one inline calibration unit 20; 20a for each test port 11, 11a. The number of test ports of the VNA 10 is this is typically significantly lower than the number of output ports 32 of the switch matrix 30. For instance, the switch matrix 30 could have 24 or 32 output ports, while the VNA 10 could have two or four test ports 11, 11a. Since the VNA 10 typically exhibits a much stronger drift than the switch matrix 30, it is sufficient if the first set of error terms (via the first calibration measurement) is recalculated much more often than the second set of error terms (via the second calibration measurement).

For instance, a calibration procedure of the system 1 can comprise the following steps:
1.) Perform a calibration at the VNA ports 11, 11a using the inline calibration units 20, 20a to calibrate the VNA calibration at its test ports 11, 11a (i.e., in a calibration plane between test ports 11, 11a and switch matrix 30). This may refer to the first calibration measurement.
2.) Perform a user calibration at the multiple output ports 32 of the switch matrix 30. This may refer to the second calibration measurement and comprise calibration measurements with open, short, match and through calibration standards.
3.) Combine the calibration results of steps 1 and step 2 using an algorithm to perform a VNA calibration in a calibration plane after the switch matrix output ports 32.
4.) After some time, when drift starts to affect the accuracy, the calibration with the inline calibration units 20, 20a is repeated and the algorithm is updated with the results. For instance, steps 1 and 3 can be performed automatically (e.g., on a regular schedule or after each DUT measurement). In this way, the impact of a drift of the VNA 10 can be eliminated without having to perform the user calibration (step 2) each time. For instance, step 2 can be repeated significantly less frequently as the drift of the switch matrix 30 is expected to be much lower compared to the VNA drift.

FIG. 3 shows an exemplary depiction of the system 1 wherein the calibration planes of step 1 and 2 are indicated.

For instance, the results of the VNA port 11, 11a calibration and the user calibration (e.g., the first and the second set of error terms) can be fed to the algorithm which calculates correction terms for the VNA based on these results. If only the first calibration measurement (step 1) is carried out, the algorithm can update the correction terms based on a VNA drift derived from the results of the first calibration measurement.

The inline calibration units 20, 20a could also be units without the further through connection 29. In this case, at least drift errors for return loss measurements can be removed when performing the calibration.

Alternatively, the through connection between the calibration units 20, 20a (in calibration mode) could also be realized by an additional path 35 through the switch matrix 30, as indicated in FIG. 3. For instance, the through connection can be an unknown through when a UOSM calibration procedure is used, which simplifies the setup.

A further alternative calibration procedure is to calibrate the VNA 10 at the test ports 11, 11a only with the inline calibration units 20, 20a and de-embed the paths of the switch matrix 30. This procedure can be carried out as follows:
1.) Calibrate the VNA 10 at the test ports 11, 11a with the inline calibration units 20, 20a.
2.) Measure the paths of the switch matrix 30. This can be done by a calibration measurement at the output ports 32 which comprises measurements with open, short and match calibration standards (OSM calibration), but without a through calibration standard.
3.) De-embed the paths measured in step 2 from the measurement results.
4.) After some time, when drift starts to affect the accuracy, the calibration with the calibration units 20, 20a is repeated (e.g., steps 1 and 3 are performed automatically). Thus, the impact of VNA drift can be eliminated.

The first and/or the second calibration unit 20, 20a can be automatic calibration (auto cal.) units. Also, the calibration module(s) 60 used for the user calibration could be automatic calibration units. The system 1 can form a set which comprises the VNA 10, the inline calibration unit(s) 20, 20a and the switch matrix 30.

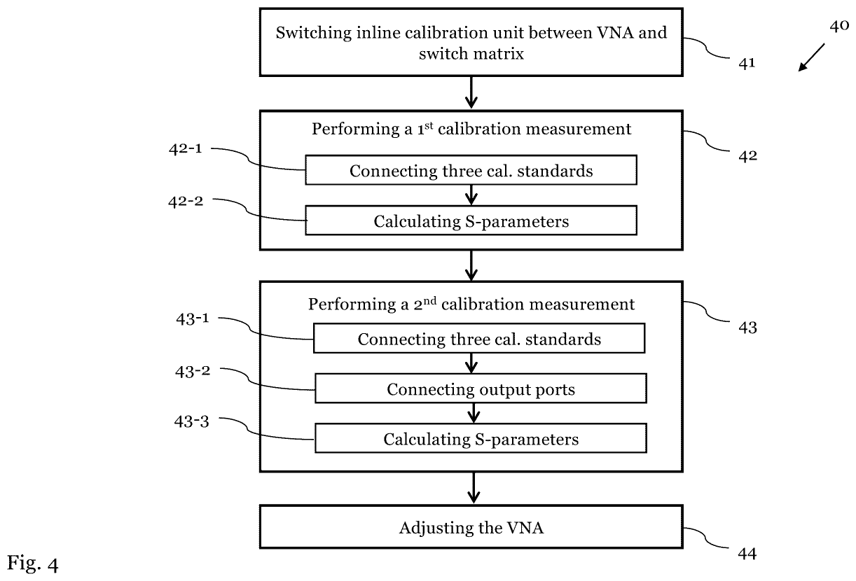

FIG. 4 shows a flow chart of a method 40 for calibrating a test and/or measurement system according to an embodiment. For instance, the calibration method 40 can be carried out with the system 1 as shown in any one of FIGS. 1-3.

The method 40 comprises the steps of: switching 41 an inline calibration unit between the test port of the VNA and the input port of the switch matrix, wherein the inline calibration unit comprises at least three different calibration standards; performing 42 a first calibration measurement comprising the steps of: alternately connecting 42-1 the at least three different calibration standards to the test port of the VNA, and calculating 42-2 a first set of error terms with the VNA. The method 40 further comprises the step of performing 43 a second calibration measurement comprising the steps of: alternately connecting 43-1 at least three different calibration standards to a number of output ports of the switch matrix, alternately connecting 43-2 the number of output ports of the switch matrix to the VNA via the switch matrix, and calculating 44 a second set of error terms with the VNA.

The method 40 may comprise the further step of adjusting 44 the VNA based on the calculated first and/or second set of error terms. The error terms can be used to adjust internal settings of the VNA in order to correct a drift.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above-described embodiments. Rather, the scope of the disclosure should be defined in accordance with the following claims and their equivalents.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the present disclosure may have been disclosed with respect to only one of several implementations, such feature may be combined with one or more other features of the other implementations as may be desired and advantageous for any given or particular application.

1. A test and/or measurement system, comprising:
a vector network analyzer, VNA, comprising a test port for forwarding RF signals;
a switch matrix comprising an input port which is arranged for being connected to the test port of the VNA, and a plurality of output ports which are arranged for being connected to a device-under-test, wherein the switch matrix is configured to electrically connect the input port to one of the plurality of output ports; and
an inline calibration unit which is switched between the test port of the VNA and the input port of the switch matrix;
wherein the inline calibration unit comprises at least three different calibration standards;
wherein the inline calibration unit is operable in a calibration mode and in a normal mode;
wherein, in the calibration mode, the inline calibration unit is configured to alternately connect the at least three different calibration standards to the test port of the VNA; and,
wherein, in the normal mode, the inline calibration unit is configured forward an RF signal received from the VNA to the switch matrix.

2. The test and/or measurement system of claim 1,
wherein the VNA is configured to perform a first calibration measurement if the first inline calibration unit is operated in the calibration mode;
wherein the first calibration measurement comprises calculating a first set of error terms.

3. The test and/or measurement system of claim 1,
wherein the VNA is configured to perform a second calibration measurement if the inline calibration unit is operated in the normal mode;
wherein during the second calibration measurement at least three different calibration standards are alternately connected to a number of output ports of the switch matrix which are alternately connected to the input port; and
wherein the second calibration measurement comprises calculating a second set of error terms.

4. The test and/or measurement system of claim 2,
wherein the VNA is configured to perform the first calibration measurement more frequently than the second calibration measurement.

5. The test and/or measurement system of claim 1,
wherein the inline calibration unit is arranged in: a housing of the VNA, a housing of the switch matrix, or a separate housing.

6. The test and/or measurement system of claim 1,
wherein the inline calibration unit comprises an impedance tuner and/or a power meter and/or a phase reference.

7. The test and/or measurement system of claim 1,
wherein the VNA comprises a further test port for forwarding RF signals;
wherein the switch matrix comprises a further input port which is arranged for being connected to the further test port of the VNA, wherein the switch matrix is configured to electrically connect the further input port to a further one of the plurality of output ports.

8. The test and/or measurement system of claim 7, comprising:
a further inline calibration unit which is switched between the further output port of the VNA and the further input port of the switch matrix;
wherein the further inline calibration unit comprises at least three different further calibration standards.

9. The test and/or measurement system of claim 8,
wherein the further inline calibration unit is operable in a calibration mode and in a normal mode;
wherein, in the calibration mode, the further inline calibration unit is configured to alternately connect the at least three different further calibration standards to the further test port of the VNA; and, in the normal mode, the further inline calibration unit is configured forward an RF signal received from the VNA to the switch matrix.

10. The test and/or measurement system of claim 9,
wherein the inline calibration unit and the further inline calibration unit are configured to at least temporarily establish a through connection between the test port and the further test port of the VNA when they operate in the calibration mode.

11. The test and/or measurement system of claim 8,
wherein the inline calibration unit and the further inline calibration unit are arranged in a shared housing or in separate housings or in the switch matrix or in the VNA.

12. The test and/or measurement system of claim 9,
wherein the VNA is configured to control the calibration unit and the further calibration unit to be in the calibration mode or the normal mode.

13. The test and/or measurement system of claim 1,
wherein the VNA comprises a number of test ports, wherein the system comprises one inline calibration unit for each of the number of test ports.

14. A method for calibrating a test and/or measurement system,
wherein the test and/or measurement system comprises a vector network analyzer, VNA, and a switch matrix; wherein the VNA comprise a test port for forwarding RF signals, and wherein the switch matrix comprises an input port and a plurality of output ports;
the method comprising the steps of:
switching an inline calibration unit between the test port of the VNA and the input port of the switch matrix, wherein the inline calibration unit comprises at least three different calibration standards;
performing a first calibration measurement comprising the steps of:
alternately connecting the at least three different calibration standards to the test port of the VNA, and
calculating a first set of error terms with the VNA;
performing a second calibration measurement comprising the steps of:
alternately connecting at least three different calibration standards to a number of output ports of the switch matrix
alternately connecting the number of output ports of the switch matrix to the VNA, and
calculating a second set of error terms with the VNA.

15. The method of claim 14, comprising the further step of:
adjusting the VNA based on the calculated first and/or second set of error terms.
